(19) United States
(12) Patent Application Publication
(10) Pub. No.: US 2019/0173698 A1
(43) Pub. Date: Jun. 6, 2019

(54) DIRECT CURRENT REMOVAL CIRCUIT

(71) Applicant: MStar Semiconductor, Inc., Hsinchu Hsien (TW)

(72) Inventors: Teng-Han TSAI, Hsinchu Hsien (TW); Tai-Lai TUNG, Hsinchu Hsien (TW)

(21) Appl. No.: 16/102,789

(22) Filed: Aug. 14, 2018

(30) Foreign Application Priority Data
Dec. 1, 2017 (TW) 106142117

(51) Int. Cl. H04L 25/06; H03D 3/00; H04B 1/04

(52) U.S. Cl. CPC H04L 25/061; H03D 2200/009; H04B 1/0475; H03D 3/008

(57) ABSTRACT

A direct current (DC) removal circuit is coupled to a radio-frequency (RF) module, which includes a local oscillator. The DC removal circuit includes: a waveform generator, generating a digital waveform signal having an average value that is smaller than a resolution of a converter coupled to the RF module; a digital adder, coupled to the waveform generator, adding the digital waveform signal to a digital DC value to generate an addition result; and a digital subtractor, subtracting the addition result from a digital signal to generate a subtraction result, so as to compensate leakage caused by the local oscillator.

This application claims the benefit of Taiwan application Serial No. 106142117, filed Dec. 1, 2017, the subject matter of which is incorporated herein by reference.

### BACKGROUND OF THE INVENTION

### Field of the Invention

The invention relates to a direct current (DC) removal circuit, and more particularly to a DC removal circuit capable of accurately compensating leakage caused by a local oscillator.

### Description of the Related Art

In a communication device, a radio-frequency (RF) module may convert a baseband signal to an intermediate-frequency (IF) signal or even to an RF signal by using a mixer and a local oscillator. A local oscillator generates leakage during operation, which results in a direct-current (DC) offset in an output signal of the RF module.

There are currently techniques that use a digital circuit to compensate the DC offset caused by a local oscillator. Taking a transmitting end for example, the transmitting end may first subtract a digital DC value from a digital signal before the digital signal is converted to an analog transmission signal through a digital-to-analog converter (DAC). An RF module can convert the analog transmission signal to an IF signal. Although a local oscillator causes leakage and hence a DC offset, the DC component in the IF signal can be alleviated or eliminated because the digital DC value has been previously subtracted. One advantage of using a digital circuit to compensate the DC offset is that an analog circuit is simpler in implementation. However, because an error between the DC offset and the digital DC value is restricted by the resolution of the DAC, the effect of DC removal is limited.

Therefore, there is a need for a solution that overcomes the above issues.

### SUMMARY OF THE INVENTION

It is a primary object of the present invention to provide a direct current (DC) removal circuit capable of accurately compensating leakage caused by a local oscillator so as to improve the issues of the prior art.

The present invention discloses a DC removal circuit, which is coupled to a radio-frequency (RF) module including a local oscillator. The DC removal circuit is for compensating leakage caused by the local oscillator, and includes: a waveform generator, generating a digital waveform signal having an average value, which is smaller than a resolution of a converter coupled to the RF module; a digital adder, coupled to the waveform generator, adding the digital waveform signal to a digital DC value to generate an addition result; and a digital subtractor, subtracting the addition result from a digital signal to generate a subtraction result, so as to compensate the leakage caused by the local oscillator.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 is a block diagram of a direct current (DC) removal circuit according to an embodiment of the present invention;

FIG. 2 is a waveform diagram of a DC value a digital waveform signal according to an embodiment of the present invention;

FIG. 3 is a block diagram of a waveform generator according to an embodiment of the present invention;

FIG. 4 is a schematic diagram of a counter signal and a digital waveform signal according to an embodiment of the present invention; and

FIG. 5 is a block diagram of a DC removal circuit according to another embodiment of the present invention.

### DETAILED DESCRIPTION OF THE INVENTION

To resolve the issues of the prior art, in which an error between a direct-current (DC) offset and a digital DC value is restricted by the resolution of a digital-to-analog converter (DAC) and hence a limited DC removal effect, apart from subtracting a digital DC value, the present invention further subtracts a digital waveform signal so as to more accurately compensate the leakage caused by a local oscillator.

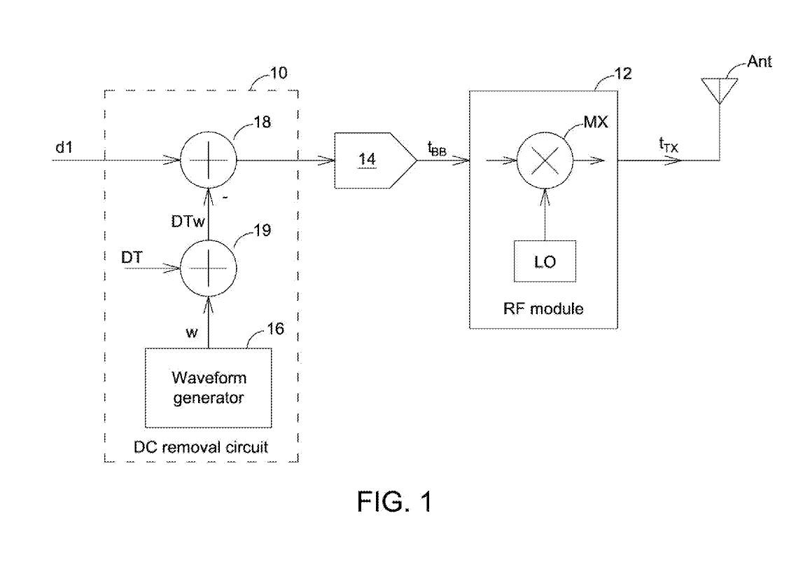

More specifically, FIG. 1 shows a block diagram of a DC removal circuit 10 according to an embodiment of the present invention. Referring to FIG. 1, the DC removal circuit 10 is provided at a transmitting end, and is coupled to a radio-frequency (RF) module 12. The RF module 12 converts a baseband analog signal t_{BB} outputted from the DC removal circuit 10 to an intermediate frequency (IF) or even an RF to generate an RF transmission signal t_{TX}, which is then transmitted through an antenna Ant to the atmosphere. The RF module 12 includes a mixer MX and a local oscillator LO, which convert the baseband analog signal t_{BB} to an intermediate frequency (IF) signal or even an RF signal. During the operation of the local oscillator LO, leakage is generated and thus causing a DC offset in the RF transmission signal t_{TX}. From the perspective of baseband, the RF module 12 equivalently adds a DC offset AT (in an analog value) to the baseband analog signal t_{BB}.

The DC removal circuit 10 is coupled to a digital-to-analog converter (DAC) 14, and includes a waveform generator 16, a digital adder 19 and a digital subtractor 18. The DC removal circuit 10 receives a digital signal d1 to generate the baseband analog signal t_{BB}, wherein the digital signal d1 may be a digital transmission signal to be transmitted by a transmitting end. The DAC 14 has a resolution Δ, which may be represented as Δ=V_{FSW}/(2W^{L-1}), where V_{FSW} represents a voltage amplitude range (equivalent to a full swing range) acceptable to the DAC 14, and WL represents a bit count (equivalent to a wordlength) acceptable to the DAC 14. The waveform generator 16 generates a digital waveform signal w having an average value Ave, wherein the average value Ave is smaller than the resolution Δ of the DAC (that is, the average value Ave may be represented as Ave=r*Δ, where 0<r,1). The digital adder 19 is coupled to the waveform generator 16, and adds the digital waveform signal w to a digital DC value DT to generate an addition result DTw. The digital subtractor 18 subtracts the addition result DTw from the digital signal d1 so as to compensate the leakage caused by the local oscillator LO.

It should be noted that, the digital DC value DT is a digital DC value closest to the DC offset AT when the wordlength of the DAC 14 is WL, and the effect of approximating the DC offset AT by the digital DC value DT is limited due to the restriction of the resolution Δ of the DAC 14. In the present invention, the digital waveform signal w (having the average value Ave smaller than the resolution Δ) is generated by the waveform generator 16, such that an equivalent value of the addition result DTw having passed through DAC 14 and the RF module 12 better approximates the DC offset AT, thus more accurately compensating the leakage caused by the local oscillator LO.

More specifically, the digital waveform signal w may be a periodical pulse sequence signal and consists of multiple positive pulses. There are N pulse widths and k positive pulses in one period of the digital waveform signal w. When the positive pulse amplitude is one resolution Δ, the average value Ave of the digital waveform signal w may be Ave=(k/N)*Δ (i.e., r=k/N).

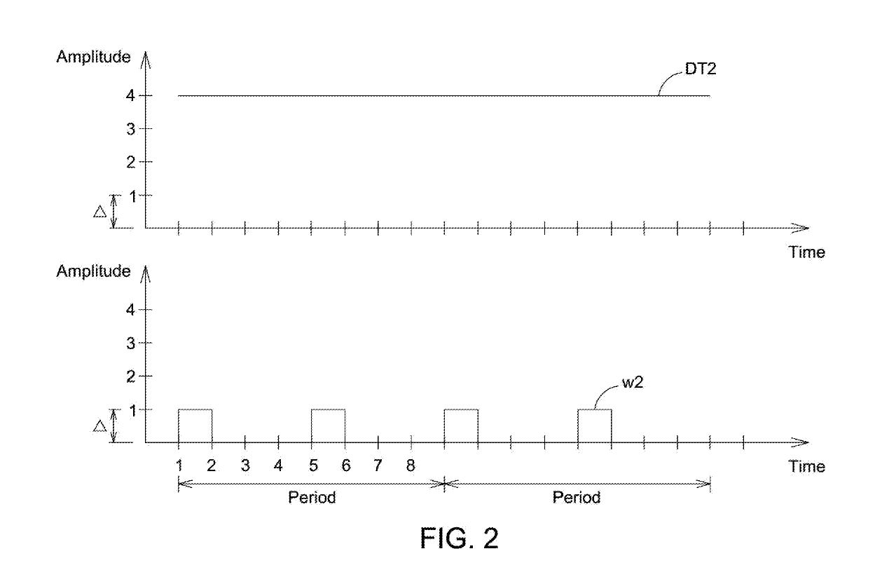

For example, FIG. 2 shows a waveform diagram of a digital DC value DT2 and a digital waveform signal w2 according to an embodiment of the present invention. The digital DC value DT2 may be the digital DC value DT in FIG. 1, and the digital waveform signal w2 may be the digital waveform diagram 2 in FIG. 1. In FIG. 2, the unit of the vertical axis is one resolution Δ, and the unit of the horizontal axis is one pulse width. Taking FIG. 2 for instance, the digital DC value DT2 is 4*Δ, there are 8 pulse widths (N=8) and 2 positive pulses (k=2) in one period of the digital waveform signal w2, and the amplitude of the positive pulse may be one resolution Δ. Accordingly, the average value Ave corresponding to the digital waveform signal w2 is (¼)*Δ.

Further, the waveform generator 16 may generate periodical pulse sequence signals as the digital waveform signal w according to the number N of pulse widths and the number k of positive pulses in one period. The method according to which the waveform generator 16 generates periodical pulse sequence signals is not limited. For example, the waveform generator 16 may first generate a counter signal cnt, and adds the value of the counter signal cnt by 1 after one clock cycle of the digital circuit, and may subtract (N/k−1) from the counter value cnt when the value of the counter value cnt is greater than or equal to (N/k). On the other hand, when the value of the counter value cnt is 0 or is greater than or equal to (N/k), the waveform generator 16 outputs a positive pulse; when the value of the counter value cnt is smaller than (N/k), the waveform generator 16 outputs 0.

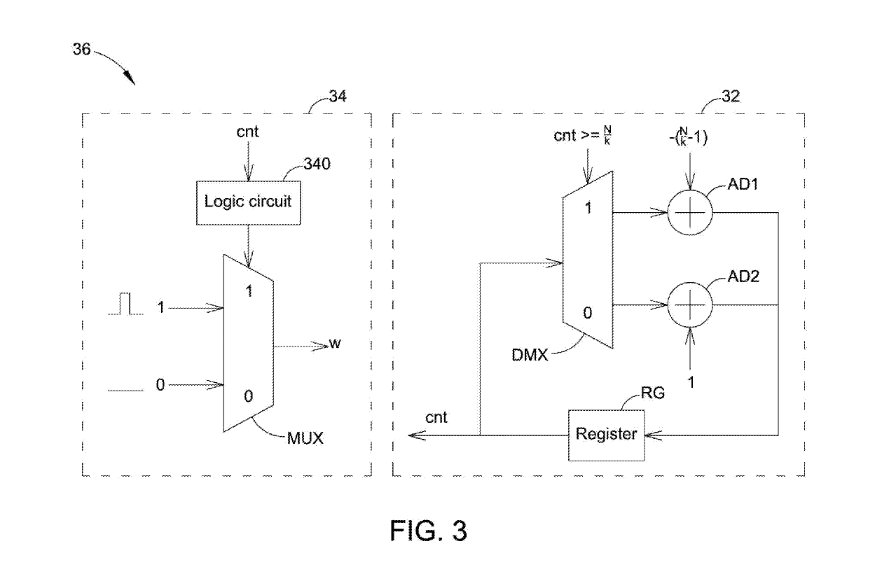

More specifically, FIG. 3 shows a block diagram of a waveform generator 36 according to an embodiment of the present invention. Referring to FIG. 3, the waveform generator 36 may be used to implement the waveform generator 16, and includes a counter signal generator 32 and an output unit 34. The counter signal generator 32 includes a register RG, a demultiplexer DMX, and adders AD1 and AD2. The counter signal generator 32 outputs a value stored in the register RG as the counter signal cnt. When the counter signal generator 32 initially starts to operate, the counter signal generator 32 sets the value in the register RG to 0. After each clock cycle, the adder AD2 adds 1 to the value in the register RG and stores the result in the register RG, and so the value in the register RF (i.e., the counter value cnt) increases with time. When the value in the register RG is greater than or equal to (N/k), the adder AD1 subtracts (N/k−1) from the value in the register RG and stores the result in the register RG. Thus, the value in the register (i.e., the counter value cnt) cyclically changes between 1 and N/k+1. Further, the output unit 34 includes a logic circuit 340 and a multiplexer MUX. The logic circuit 340 receives the counter signal cnt generated by the counter signal generator 32. When the logic circuit 34 determines that the value of the counter signal cnt is 0 or is greater than or equal to (N/k), the logic circuit 340 generates a control signal to cause the waveform generator 36 to output a positive pulse; when the logic circuit 340 determines that the counter value cnt is smaller than (N/k), the logic circuit 340 generates a control signal to cause the waveform generator 36 to output 0.

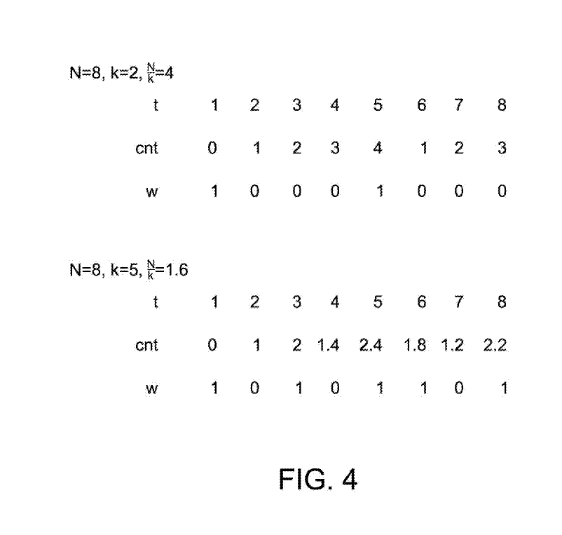

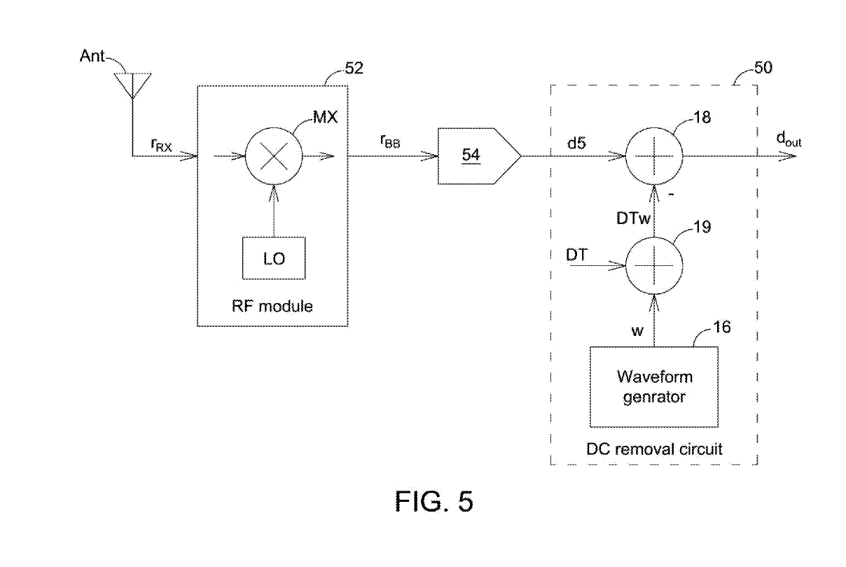

For example, FIG. 4 shows a schematic diagram of the counter value cnt generated by the counter signal generator 32 and the digital waveform signal w generated by the output unit 34. In FIG. 5, t represents a time index of using a clock cycle of a digital circuit as a unit, where t=1 represents a first clock cycle, and so forth. For better understanding, the counter signal cnt and the digital waveform signal w are both represented by numerical values; the value 1 of the digital waveform signal w in a clock cycle indicates that the waveform generator 36 outputs a positive pulse in the clock cycle, and the value 0 of the digital waveform signal w in a clock cycle indicates that the waveform generator 36 outputs 0 in the clock cycle. The upper half of FIG. 4 shows values of the counter signal cnt and the digital waveform signal w in a situation where the number N of pulse widths is 8 and the number k of positive pulses is 2 (generated by the counter signal generator 32 and the output unit 34), and the lower half of FIG. 4 shows values of the counter signal cnt and the digital waveform signal w in a situation where the number N of pulse widths is 8 and the number k of positive pulses is 5. As seen from FIG. 4, the counter signal generator 32 and the output unit 34 can generate periodical pulse sequence signals as the digital waveform signal w according to the number N of the pulse widths and the number k of positive pulses.

Further, when the number N of pulse widths in one period of the digital waveform signal w is constant, the number k of positive pulses may be set to 1, . . . and N−1 to generate respectively corresponding digital waveform signals w₁, . . . and w_{N-1} (of which average values Ave are respectively ((1/N)*Δ, . . . and ((N−1)/N*Δ)). The digital waveform signals w₁, . . . and w_{N-1} are respectively applied to the digital adder 19, and the DC removal effect thereof is recorded. Form the records, an optimal number k* of positive pulses and an optimal digital waveform signal w_{k*} as well as the optimal number k* of positive pulses are respectively applied to the counter signal generator 32 and the output unit 34 to generate the digital waveform signal w as the optimal digital waveform signal w_{k*}.

It is known from the above description that, in the present invention, a waveform generator is used to generate a periodical digital waveform signal (which may be a periodical pulse sequence signal), which has an average Ave represented as Ave=r*Δ, where r may be a rational number between 0 and 1. Thus, an equivalent value of the addition result DTw having passed through the DAC 14 and the RF module 12 better approximates the DC offset AT to more accurately compensate the leakage caused by the local oscillator LO.

For example, when N=10 and k=4, compared to the prior art (which uses merely the digital DC value for DC removal/compensation), the DC removal circuit of the present invention can reduce the residual DC component after the compensation by about 20 dB. When N=20 and k=9, compared to the prior art, the DC removal circuit of the present invention can reduce the residual DC component after the compensation by about 40 dB; that is, the present invention is capable of better compensating the leakage caused by the local oscillator LO.

It should be noted that, the foregoing embodiments are for explaining the concept of the present invention, and a person skilled in the art can accordingly make different modifications that are not limited by the above examples. For example, the amplitude of the positive pulses in the digital waveform signal w is not limited to being one resolution Δ, but may be any positive value, given that the average value Ave of the digital waveform signal w is smaller than the resolution Δ—such modification is within the scope of the present invention.

Further, the DC removal circuit of the present invention may be provided at a receiving end. FIG. 5 shows a block diagram of a DC removal circuit 50 according to an embodiment of the present invention. The DC removal circuit 50 is provided at a receiving end, and is coupled to an RF module 52 through an analog-to-digital converter (ADC) 54. The RF module 52 converts an RF analog signal r_{RX} to an IF or even to a baseband to generate a baseband analog signal r_{BB}. The ADC 54 converts the baseband analog signal r_{BB} to a digital signal d5, which may be a baseband digital reception signal received by the receiving end. The DC removal circuit 50 receives the digital signal d5, and includes a waveform generator 16, a digital adder 19 and a digital subtractor 18. The digital subtractor 18 subtracts the addition result DTw of the digital DC value DT and the digital waveform signal w from the digital signal d5 to generate a subtraction result dₒᵤₜ, which is then outputted by the DC removal circuit 50. Other operation details of the DC removal circuit 50 are identical to those of the DC removal circuit 10, and are omitted herein.

In conclusion, in the present invention, a periodical digital waveform signal is generated by a waveform generator, wherein an average value of the digital waveform signal is smaller than the resolution of a DAC (or an ADC), thus providing an enhanced DC removal effect.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A direct current (DC) removal circuit, coupled to a radio-frequency (RF) module, the RF module comprising a local oscillator, the DC removal circuit for compensating leakage caused by the local oscillator, the DC removal circuit comprising:
a waveform generator, generating a digital waveform signal having an average value, which is smaller than a resolution of a converter coupled to the RF module;
a digital adder, coupled to the waveform generator, adding the digital waveform signal to a digital DC value to generate an addition result; and
a digital subtractor, subtracting the addition result from a digital signal to generate a subtraction result so as to compensate the leakage caused by the local oscillator.

2. The DC removal circuit according to claim 1, provided at a transmitting end; wherein, the digital subtractor outputs the subtraction result to the converter, the converter converts the subtraction result to an analog signal, and the RF module generates a transmission signal according to the analog signal.

3. The DC removal circuit according to claim 1, provided at a receiving end; wherein, the RF module generates a reception signal, the converter converts the reception signal to the digital signal, and the DC removal circuit outputs the subtraction result.

4. The DC removal circuit according to claim 1, wherein the digital waveform signal is a periodical pulse sequence signal, there are N pulse widths and k positive pulses in one period of the digital waveform signal, and the waveform generator generates the digital waveform signal according to the number N of the pulse widths and the number k of positive pulses.

5. The DC removal circuit according to claim 4, wherein an amplitude of each positive pulse is associated with the resolution of the converter.

6. The DC removal circuit according to claim 4, wherein the waveform generator generates the digital waveform signal according to the number N of pulse widths and the number k of positive pulses by performing steps of:
generating a counter signal;
when a value of the counter signal is 0 or is greater than or equal to (N/k), the waveform generator outputting a positive pulse; and
when the value of the counter signal is smaller than (N/k), the waveform generator outputting 0.

7. The DC removal circuit according to claim 6, wherein the waveform generator generates the counter signal by performing steps of:
setting a value of a register to 0, adding the value of the register by 1 after each clock cycle, and storing the result in the register;
when the value stored in the register is greater than or equal to (N/k), subtracting (N/k−1) from the value of the register, and storing the result in the register; and
outputting the value of the register as the counter signal.

8. The DC removal circuit according to claim 4, wherein the waveform generator comprises:
a counter signal generator, generating a clock signal, the counter signal generator setting a value of the register to 0, adding the value of the register by 1 after each clock cycle, and storing the result in the register; when the value of the register is greater than or equal to 1, the counter signal generator subtracting (N/k−1) from the value of the register, storing the result in the register, and outputting the value of the register as the counter signal; and
an output unit, receiving the counter signal;
wherein, when the value of the counter signal is 0 or is greater than or equal to (N/k), the waveform generator outputs a positive pulse; when the value of the counter signal is smaller than (N/k), the waveform generator outputs 0.
